(19) United States
(12) Patent Application Publication
(10) Pub. No.: US 2026/0165131 A1
(43) Pub. Date: Jun. 11, 2026

(54) MOSFET WITH TEMPERATURE DETECTION FEATURE

(71) Applicant: Infineon Technologies AG, Neubiberg (DE)

(72) Inventor: Rainald Sander, Oberhaching (DE)

(21) Appl. No.: 19/412,213

(22) Filed: Dec. 8, 2025

(30) Foreign Application Priority Data
Dec. 10, 2024 (DE) 102024136955.8

(51) Int. Cl. H10W 40/50

(52) U.S. Cl. CPC H10W 40/50

(57) ABSTRACT

In accordance with an embodiment, a field-effect transistor (FET) chip with integrated overtemperature protection, the FET chip including: a FET comprising a FET-gate comprising a first material, a FET-body arranged between a FET-source and a FET-drain, and a drain-source field oxide as a first isolator, the drain-source field oxide being arranged between the FET-gate and the FET-body; a temperature sensor conﬁgured for sensing a temperature of the FET, the temperature sensor comprising the first material; and a second isolator arranged between the FET and the temperature sensor.

### CROSS-REFERENCE TO RELATED APPLICATIONS

This application claims the benefit of German Patent Application No. 102024136955.8, filed on December 10, 2024, which application is hereby incorporated herein by reference.

### TECHNICAL FIELD

The invention relates to the field of field-effect transistors (FETs), particularly to a FET chip with an integrated overtemperature protection. The invention further relates to a FET arrangement, a manufacturing method, and to a use.

### BACKGROUND

To protect a power switch against destruction by an overtemperature situation, monitoring the temperature of the power switch is essential. However, at least some temperature sensing elements may have a high thermal transfer resistance, and/or the temperature sensing elements may impose an additional manufacturing step.

### SUMMARY

Some embodiments relate to overtemperature protection for a FET-based power switch.

One aspect relates to a field-effect transistor, FET, chip with integrated overtemperature protection. The FET chip comprises a FET, comprising a FET-gate, consisting of a first material, a FET-body, arranged between a FET-source and a FET-drain, and a drain-source field oxide as a first isolator, the drain-source field oxide being arranged between the FET-gate and the FET-body. The FET chip further comprises a temperature sensor, conﬁgured for sensing a temperature of the FET, the temperature sensor (R1) consisting of the first material, and a second isolator, that is arranged between the FET and the temperature sensor.

The field-effect transistor, FET, may be a FET of any kind. Examples may comprise, but are not limited to a MOSFET, PMOS, NMOS, CMOS, or an IGBT. The FET comprises a FET-gate and a FET-body. The FET-body is arranged between a FET-source and a FET-drain, and/or is the material the FET-source and the FET-drain is built of. The material may be a semiconductor material. The FET-gate and the FET-body is electrically isolated by a drain-source field oxide as a first isolator, which is arranged between the FET-gate and the FET-body. The first isolator may be different from the drain-diffusion and/or the source-diffusion material.

Besides the FET, the FET chip comprises a temperature sensor, which is conﬁgured for sensing a temperature of the FET. The temperature sensor may be used as an integrated overtemperature protection of the FET chip, and/or may be used as a basis for building an integrated overtemperature protection of the FET chip. It is advantageous that both the FET-gate and the temperature sensor consist of the same material. This may, for instance, ease the manufacturing of the FET chip. Between the FET and the temperature sensor, a second isolator is arranged. The second isolator may comprise silicon dioxide. In at least some cases, the second isolator may be of the same material or type of material as the first isolator.

The FET chip or its components, respectively, may advantageously be integrated by layout, i.e. not by means of diffusion. Hence, the same process for the FET, the temperature sensor and the second isolator may be used. In other words, for the integrated overtemperature protection no “process adder” (i.e. an additional process step or manufacturing step) becomes necessary, nor any change of the FET. Furthermore, there is a very low thermal transfer resistance between the FET chip and the temperature sensor, with a high electric resistance between the FET chip and the temperature sensor. This may contribute to ensuring a highly precise temperature measurement, particularly because the temperature sensor can be arranged very close to the FET.

In various embodiments, the first material is polycrystalline silicon.

In various embodiments, the first isolator is of SiO₂ (silicon dioxide). This material can be manufactured in a precise way, with well-defined properties. In at least some cases, the second isolator may be of the same material or type of material as the first isolator.

In various embodiments, the FET is a power FET, designed for a current between 1 A and 1000 A, for example between 10 A and 100 A. For power FETs, monitoring its temperature may be essential.

In various embodiments, the FET is a MOSFET (Metal Oxide Semiconductor Field-Effect Transistor), a PMOS (P-Channel Metal-Oxide-Semiconductor), an NMOS N-Channel Metal-Oxide-Semiconductor), a CMOS (Complementary Metal-Oxide-Semiconductor), a GaN-FET (Gallium Nitride FET) or an IGBT (Insulated-Gate Bipolar Transistor).

In various embodiments, the temperature sensor is a resistor.

In various embodiments, the temperature sensor is a positive temperature coefficient thermistor, PTC.

In various embodiments, the temperature sensor is a negative temperature coefficient thermistor, NTC.

Both in the case of a PTC and of an NTC, the temperature sensor comprises or consists of polycrystalline silicon. Hence, for both types of the temperature sensor, the same process as for the FET can be used. Of course, for building a PTC or an NTC, the properties of the polycrystalline silicon – e.g. its doping – need to be varied.

In some embodiments, the temperature sensor comprises a plurality of sensors or sensor elements. The plurality of sensors may be arranged close together, and/or on different positions of the FET chip. By using the plurality of sensors, the precision of the temperature measurement may be further increased. And/or, the plurality of sensors may be used for redundancy purposes.

In some embodiments, the plurality of sensors – which function as temperature sensor – are arranged in a Wheatstone bridge. This arrangement may increase the precision of the measurement.

In some embodiments, the overtemperature protection is conﬁgured to limit the temperature of the chip to a maximum temperature of 175°C, and/or to a maximum temperature of 200°C. Particularly when using a plurality of sensors as temperature sensor, the maximum allowed temperature may be different between the sensors. This may be used as a basis for stepwise reactions on the temperature. In some cases, the “stepwise reactions” may be implemented without additional computing power and/or computing means. This may contribute to a highly reliable and/or robust reaction on overtemperature. The maximum temperature (or the maximum allowed temperature) may depend on the specification of the FET, e.g. it may be different for standard environment or for rough environment, e.g. for vehicles.

An aspect relates to a FET arrangement for an overtemperature protection. The FET arrangement comprises a FET chip as described above and/or below. The FET arrangement further comprises a connecting element that is arranged at the FET chip and electrically connecting the FET-body to a source-terminal (and/or to a drain-terminal) of the FET chip. The FET arrangement further comprises a second chip, comprising a switch. The switch is conﬁgured for being controlled by a temperature sensor of the FET chip. The temperature sensor is part of the FET chip. The FET chip may have a size of about 10 mm² to 20 mm². One end of the temperature sensor is connected to an input of the switch.

In some embodiments, the connecting element is designed as a clip plate. The clip plate or “clip” may be a solid connection element, e.g. a piece of metal comprising or consisting of copper (Cu) or aluminum (Al).

In some embodiments, the connecting element is designed as a flexible ribbon. The flexible ribbon may be a flat, broad wire. The flexible ribbon may be of aluminum.

In some embodiments, the connecting element is designed as a bond-wire.

In various embodiments, the FET arrangement further comprises a leadframe, wherein the leadframe is arranged at the FET chip. The leadframe is a metal structure inside a chip package that carries signals from the die to the outside, i.e. supporting the chips with leads.

In some embodiments, the switch is a component, having an output signal that is a function of a resistance value of the temperature sensor. The component may be a semiconductor, a plurality of semiconductors, or a circuit.

In some embodiments, the switch is a second FET.

In some embodiments, the switch is a thyristor.

In various embodiments, the FET chip and the second chip are designed as a chip-on-chip arrangement or “chip-by-chip”. This arrangement may save space, i.e. it may lead to a particularly compact design of the FET arrangement.

In various embodiments, a temperature that triggers the overtemperature protection is a temperature over 175°C, and/or a temperature over 200°C. Particularly when using a plurality of sensors as temperature sensor, the maximum allowed temperature may be different between the sensors, and/or different temperatures may trigger different steps of the overtemperature protection. Triggering the overtemperature protection may comprise that the switch is opened or closed.

In some embodiments, triggering the overtemperature protection means to close the switch. In some embodiments, triggering the overtemperature protection means to open the switch. Opening or closing the switch, respectively, may depend on the type of the temperature sensor, for example if a PTC or an NTC is used. When using a plurality of sensors as a temperature sensor, the maximum allowed temperature may be different between the sensors, and/or different temperatures may trigger different steps of the overtemperature protection, and/or some of the temperature sensors may be a PTC, whereas others are an NTC. Thus, some temperature sensors may lead to closing the respective (or corresponding) switch, others may lead to opening the respective switches in overtemperature situations.

In various embodiments, the FET arrangement is designed as a surface-mounted device, SMD. This may improve its versatility.

An aspect relates to a manufacturing method for building a FET arrangement as described above and/or below. The method comprises the steps of: providing a FET chip as described above and/or below; arranging a connecting element at the FET chip; and arranging a second chip at the connecting element and/or at the FET chip, wherein the second chip comprises a switch, the switch being conﬁgured for being controlled by a temperature sensor of the FET chip.

There may be bonding wires between the FET chip and the second chip, and also from the FET chip and/or from the second chip to “outside”, e.g. to a pin or another connection arranged in the FET arrangement.

In some embodiments, the second chip is arranged besides the FET chip. Accordingly, the connecting element is arranged above or besides the FET chip.

In some embodiments, the second chip is arranged above the FET chip. Accordingly, the connecting element is arranged above or besides the FET chip.

In various embodiments, the method further comprising the step of providing a leadframe, the leadframe being arranged below or besides the FET chip.

In various embodiments, the arranging the conducting clip plate above the FET chip comprises gluing the clip plate onto the FET chip by means of a conducting glue and/or of a conducting paste.

In various embodiments, the arranging the second chip above the conducting clip plate comprises gluing the second chip onto the conducting clip plate by means of an electrically isolating glue.

An aspect relates to a use of a FET chip as described above and/or below or of a FET arrangement as described above and/or below for protecting a FET of the FET chip from overtemperature, for example for automotive applications.

For further elucidation, the disclosure is described by means of embodiments shown in the figures. These embodiments are to be considered as examples only, but not as limiting.

### BRIEF DESCRIPTION OF THE DRAWINGS

The drawings depict:

FIG. 1 schematically a FET arrangement according to an embodiment;

FIG. 2 schematically a FET arrangement according to an embodiment in a top view;

FIG. 3 schematically a FET arrangement according to an embodiment in a side view;

FIG. 4 schematically a switch or a part of a second chip according to an embodiment; and

FIG. 5 a flow diagram according to an embodiment.

### DETAILED DESCRIPTION OF ILLUSTRATIVE EMBODIMENTS

FIG. 1 shows schematically a FET arrangement 100 according to an embodiment. The FET arrangement 100 comprises a FET chip 10 and a second chip 20. The FET chip 10 comprises a FET 14 and a temperature sensor R₁. The FET 14 comprises a FET-gate G, which is connected to a gate-terminal 12. The FET-gate G consists of a first material. The FET 14 further comprises a FET-body 15, which is arranged between a FET-source S and a FET-drain D. The FET-source S is connected to a source-terminal 13, via a connecting element 18. A further or alternative connecting element (not shown) may be arranged between the FET-drain D and a drain-terminal 11. Between the FET-gate G and the FET-body 15, a drain-source field oxide (not shown) is arranged, as a first electric isolator. The first isolator may be made of SiO₂.

The temperature sensor R₁ may be designed as a resistor, as a positive temperature coefficient thermistor, PTC, or as a negative temperature coefficient thermistor, NTC. The temperature sensor R₁ consists of the first material, i.e. of the same material as the FET-gate G. The first material may be polycrystalline silicon. The temperature sensor R₁ may be implemented as one sensor, or as a plurality of sensors. The temperature sensor R₁ may comprise polycrystalline silicon. Basically, the temperature sensor R₁ may be designed for any temperature that is considered as being an overtemperature. The maximum temperature (or the maximum allowed temperature) may depend on the specification of the FET, e.g. it may be different for standard environments or for rough environments, e.g. for vehicles. Different maximum temperature values may be selected for a short-term allowed temperature and a long-term allowed temperature. Examples of the overtemperature may be 175°C, 200°C, and/or another temperature that is considered as being crucial for the FET 14. When the overtemperature is reached, the temperature sensor R₁ may fall below or exceed, respectively, a predefined resistance value. The current value of the temperature sensor R₁ can be sensed at terminals 16 and 17.

The second chip 20 of the FET arrangement 100 comprises a switch S₁. The switch S₁ is conﬁgured for being controlled by a temperature sensor R₁ of the FET chip 10, e.g. by connecting terminal 16 of the FET chip 10 with terminal 25 of the second chip 20. The switch S₁ may, for instance, be a thyristor (see FIG. 4), a second FET, or another type of switch. Depending on the type of the temperature sensor R₁ and/or on the type of the switch S₁, an overtemperature may lead to a closing or an opening of the switch S₁. Terminals 26 and 27 of the second chip 20 may be connected to a control unit (not shown), which limits and/or interrupts a current through the FET 14, thus protecting FET 14 from overtemperature.

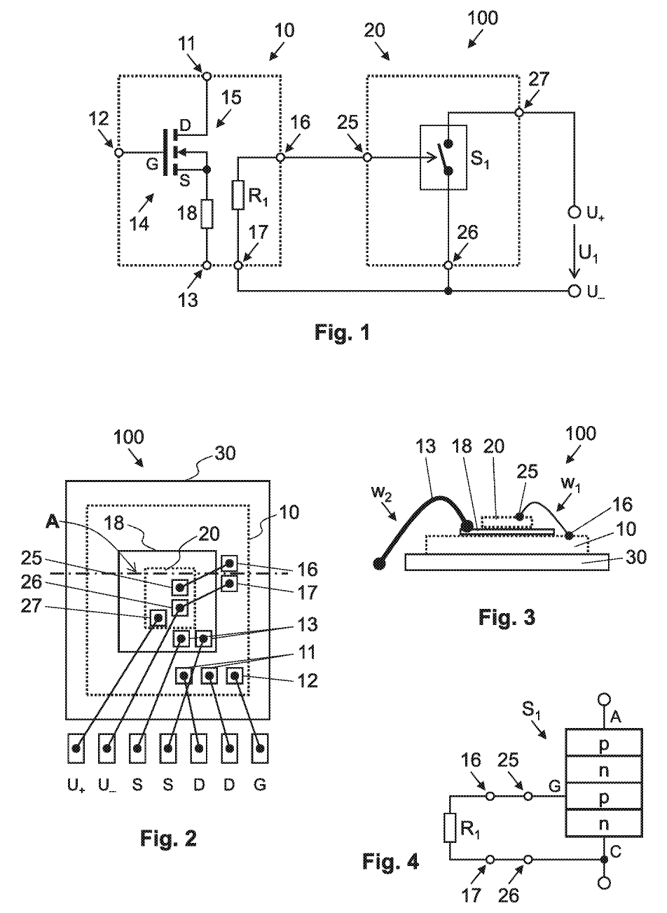

FIG. 2 shows schematically a FET arrangement 100 according to an embodiment in a top view. Same reference signs as for FIG. 1 designate same or similar components. The embodiment shown is a chip-on-chip arrangement. The lowest level of the FET arrangement 100 is a leadframe 30. Above the leadframe 30, a FET chip 10 is arranged. Above the FET chip 10, a connecting element 18 is arranged. In the embodiment shown, the connecting element 18 is designed as a so-called “clip” or clip plate. The arranging may, for instance, be done by gluing the clip plate 18 onto the FET chip 10 by means of a conducting glue. Above the connecting element 18, a second chip 20 is arranged. The arranging may, for instance, be done by gluing the second chip 20 onto the conducting clip plate 18 by means of an electrically isolating glue. The components of the FET arrangement 100 may be electrically connected by bonding wires, e.g. according to the circuit diagram shown in FIG. 1. It is clearly visible that, for example, terminal 16 of the FET chip 10 is connected to terminal 25 of the second chip 20 and to the U_{–} output-lead, which may be conﬁgured for being connected to another circuit. The power components of the FET 14 may be connected to more than one output-lead. For example, the two leads of source-terminal 13 of the FET chip 10 are connected to two leads of output-lead S. These bond-wires may be thicker than other bond-wires. A leadless implementation is possible.

FIG. 3 shows schematically a FET arrangement 100 according to an embodiment in a side view. This may be a kind of cross-section through the FET arrangement 100 of FIG. 2 along the line “A”. The same reference signs as for FIG. 2 designate the same components. Exemplary wires w₁ and w₂ are shown. Wire w₂ is thicker than w₁, because it connects the power components source-terminal 13 with an output-lead S (not shown).

FIG. 4 shows schematically a switch S₁ or a part of a second chip 20 according to an embodiment. The switch S₁ is designed as a thyristor. One end of a temperature sensor R₁ is connected to a gate G of the thyristor, via terminals 16 and 25. The other end of the temperature sensor R₁ is connected to a cathode C of the thyristor, via terminals 17 and 26. Dependent on the type of the temperature sensor R₁, the switch S₁ may become conducting when a temperature falls below or exceeds, respectively, a predefined overtemperature, which corresponds to a predefined resistance value of the temperature sensor R₁.

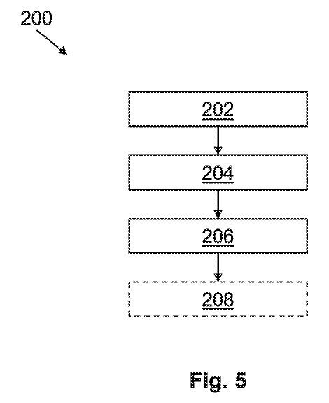

FIG. 5 shows a flow diagram 200, which describes a manufacturing method for building a FET arrangement 100 according to an embodiment. In a step 202, a FET chip 10 as described above and/or below is provided. In step 204, a connecting element 18 is arranged at the FET chip 10. In step 206, a second chip 20 is arranged at the connecting element 18. In an optional step 208, a leadframe 30 is arranged below or besides the FET chip 10.

A further aspect relates to some examples.

Example 1 relates to a field-effect transistor, FET, chip with integrated overtemperature protection. The FET chip comprises a FET, comprising a FET-gate, consisting of a first material, a FET-body, arranged between a FET-source and a FET-drain, and a drain-source field oxide as a first isolator, the drain-source field oxide being arranged between the FET-gate and the FET-body. The FET chip further comprises a temperature sensor, conﬁgured for sensing a temperature of the FET, the temperature sensor consisting of the first material; and a second isolator, arranged between the FET and the temperature sensor.

Example 2 relates to FET chip of example 1, wherein the first material is polycrystalline silicon.

Example 3 relates to FET chip of example 1, wherein the first isolator is of SiO₂.

Example 4 relates to FET chip of any one of the preceding examples, wherein the FET is a power FET, designed for a current between 1 A and 1000 A, for example between 10 A and 100 A.

Example 5 relates to FET chip of any one of the preceding examples, wherein the FET is a MOSFET, PMOS, NMOS, CMOS, a GaN-FET or an IGBT.

Example 6 relates to FET chip of any one of the preceding examples, wherein the temperature sensor is a resistor.

Example 7 relates to FET chip of any one of the preceding examples, wherein the temperature sensor is a positive temperature coefficient thermistor, PTC, or a negative temperature coefficient thermistor, NTC.

Example 8 relates to FET chip of any one of the preceding examples, wherein the temperature sensor comprises a plurality of sensors.

Example 9 relates to FET chip of example 8, wherein the plurality of sensors are arranged in a Wheatstone bridge.

Example 10 relates to FET chip of any one of the preceding examples, wherein the overtemperature protection is conﬁgured to limit the temperature of the chip to a maximum temperature of 175°C.

Example 11 relates to FET chip of any one of the examples 1 – 9, wherein the overtemperature protection is conﬁgured to limit the temperature of the chip to a maximum temperature of 200°C.

Example 12 relates to a FET arrangement for an overtemperature protection. The FET arrangement comprises a FET chip of any one of the examples 1 – 11; a connecting element, arranged at the FET chip and electrically connecting the FET-body to a source-terminal; and a second chip, comprising a switch, the switch being conﬁgured for being controlled by a temperature sensor of the FET chip.

Example 13 relates to FET arrangement of example 12, wherein the connecting element is designed as a clip plate.

Example 14 relates to FET arrangement of example 12, wherein the connecting element is designed as a flexible ribbon.

Example 15 relates to FET arrangement of example 12, wherein the connecting element is designed as a bond-wire.

Example 16 relates to FET arrangement of any one of the examples 12 – 15, further comprising a leadframe, the leadframe being arranged at the FET chip.

Example 17 relates to FET arrangement of any one of the examples 12 – 16, wherein the switch is an analog component, having an output signal that is a function of a resistance value of the temperature sensor.

Example 18 relates to FET arrangement of any one of the examples 12 – 17, wherein the switch is a second FET.

Example 19 relates to FET arrangement of any one of the examples 12 – 16, wherein the switch is a thyristor.

Example 20 relates to FET arrangement of any one of the examples 12 – 19, wherein the FET chip and the second chip are designed as a chip-on-chip arrangement.

Example 21 relates to FET arrangement of any one of the examples 12 – 20, wherein a temperature that triggers the overtemperature protection is a temperature over 175°C.

Example 22 relates to FET arrangement of any one of the examples 12 – 20, wherein a temperature that triggers the overtemperature protection is a temperature over 200°C.

Example 23 relates to FET arrangement of any one of the examples 12 – 22, wherein triggering the overtemperature protection means to close the switch.

Example 24 relates to FET arrangement of any one of the examples 12 – 22, wherein triggering the overtemperature protection means to open the switch.

Example 25 relates to FET arrangement of any one of the examples 12 – 24, wherein the FET arrangement is designed as a surface-mounted device, SMD.

Example 26 relates to a manufacturing method for building a FET arrangement of any one of the examples 12 – 25. The method comprises the steps of: providing a FET chip according to one of the examples 1 – 11; arranging a connecting element at the FET chip; and arranging a second chip at the connecting element and/or at the FET chip, wherein the second chip comprises a switch, the switch being conﬁgured for being controlled by a temperature sensor of the FET chip.

Example 27 relates to manufacturing method of example 26, wherein the second chip is arranged besides the FET chip.

Example 28 relates to manufacturing method of example 26, wherein the second chip is arranged above the FET chip.

Example 29 relates to manufacturing method of any one of the examples 26 – 28, further comprising the step of: providing a leadframe, the leadframe being arranged below or besides the FET chip.

Example 30 relates to manufacturing method of example 28 or 29, wherein arranging the conducting clip plate above the FET chip comprises gluing the clip plate onto the FET chip by means of a conducting glue and/or of a conducting paste.

Example 31 relates to manufacturing method of any one of the examples 28 – 30, wherein arranging the second chip above the conducting clip plate comprises gluing the second chip onto the conducting clip plate by means of an electrically isolating glue.

Example 32 relates to a use of a FET chip of any one of the examples 1 – 11 or of a FET arrangement of any one of the examples 12 – 25 for protecting a FET of the FET chip from overtemperature, for example for automotive applications.

What is claimed is:

1. A field-effect transistor (FET) chip with integrated overtemperature protection, the FET chip comprising:
a FET, comprising
a FET-gate comprising a first material,
a FET-body arranged between a FET-source and a FET-drain, and
a drain-source field oxide as a first isolator, the drain-source field oxide being arranged between the FET-gate and the FET-body;
a temperature sensor conﬁgured for sensing a temperature of the FET, the temperature sensor comprising the first material; and
a second isolator arranged between the FET and the temperature sensor.

2. The FET chip of claim 1, wherein the first material is polycrystalline silicon, or the drain-source field oxide comprises SiO₂.

3. The FET chip of claim 1, wherein the FET is a MOSFET, PMOS, NMOS, CMOS, a GaN-FET or an IGBT.

4. The FET chip of claim 1, wherein the temperature sensor comprises a resistor, a positive temperature coefficient thermistor (PTC) or a negative temperature coefficient thermistor (NTC).

5. The FET chip of claim 1, wherein the temperature sensor comprises a plurality of sensors.

6. The FET chip of claim 5, wherein the plurality of sensors are arranged in a Wheatstone bridge configuration.

7. A method of using the FET chip of claim 1, the method comprising:
detecting, using the temperature sensor, an overtemperature condition of the FET; and
decreasing a current flowing through the FET in response to detecting the overtemperature condition.

8. A field-effect transistor (FET) arrangement for overtemperature protection, the FET arrangement comprising:
a FET chip comprising:
a FET comprising a FET-gate comprising a first material, a FET-body arranged between a FET-source and a FET-drain, and a drain-source field oxide as a first isolator, the drain-source field oxide being arranged between the FET-gate and the FET-body,
a temperature sensor conﬁgured for sensing a temperature of the FET, the temperature sensor comprising the first material, and
a second isolator arranged between the FET and the temperature sensor;
a connecting element, arranged at the FET chip and electrically connecting the FET-body to a source-terminal; and
a second chip comprising a switch conﬁgured for being controlled by the temperature sensor of the FET chip.

9. The FET arrangement of claim 8, wherein the connecting element comprises a clip plate, as a flexible ribbon, or as a bond-wire.

10. The FET arrangement of claim 8, further comprising a leadframe,
the leadframe being arranged at the FET chip.

11. The FET arrangement of claim 8, wherein the switch is an analog component configured to provide an output signal that is a function of a resistance value of the temperature sensor.

12. The FET arrangement of claim 8, wherein the switch is a thyristor.

13. The FET arrangement of any one of claim 8, wherein the FET chip and the second chip comprise a chip-on-chip arrangement.

14. The FET arrangement of claim 8, wherein the switch is configured to close in response to the temperature sensor detecting an overtemperature condition.

15. The FET arrangement of claim 8, wherein the switch is configured to open in response to the temperature sensor detecting an overtemperature condition.

16. The FET arrangement of claim 8, wherein the FET arrangement is configured as a surface-mounted device (SMD).

17. A method, comprising:
providing a field-effect transistor (FET) chip comprising:
a FET comprising a FET-gate comprising a first material, a FET-body arranged between a FET-source and a FET-drain, and a drain-source field oxide as a first isolator, the drain-source field oxide being arranged between the FET-gate and the FET-body,
a temperature sensor conﬁgured for sensing a temperature of the FET, the temperature sensor comprising the first material, and
a second isolator arranged between the FET and the temperature sensor arranging a connecting element at the FET chip; and
arranging a second chip at the connecting element or at the FET chip, wherein the second chip comprises a switch conﬁgured for being controlled by the temperature sensor of the FET chip.

18. The method of claim 17, wherein arranging the second chip comprises arranging the second chip beside or above the FET chip.

19. The method of claim 17, further comprising providing a leadframe below or beside the FET chip.

20. The method of claim 17, wherein:
the method further comprises arranging a conducting clip plate above the FET chip by gluing the clip plate onto the FET chip using a conducting glue or a conducting paste; or
the method further comprises arranging the second chip above the conducting clip plate by gluing the second chip onto the conducting clip plate using an electrically isolating glue.
